(19) United States
(12) Patent Application Publication
(10) Pub. No.: US 2004/0164331 A1
(43) Pub. Date: Aug. 26, 2004

(54) CMOS image sensor device and process of producing the same

(76) Inventor: Chih-Wei Hung, Hsin-chu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/064,095

(22) Filed: Jun. 11, 2002

(51) Int. Cl. H01L 31/062

(52) U.S. Cl. 257/292

(57) ABSTRACT

A CMOS image sensor device including a substrate, a photodiode sensing region, a reset transistor, a source follower transistor and a buried contact (BC) is provided. The substrate has an isolation structure that defines an active region. The photodiode sensing region is located in the substrate, and the reset transistor is located on the active region of the substrate and has a source region partially connected to the photodiode sensing region. A first end of the buried contact is located on the substrate between the photodiode sensing region and the reset transistor and extends over the isolation structure to cover the periphery of the isolation structure and electrically connect the source region of the reset transistor. A second end of the buried contact is located on the active region of the substrate to be used as a gate of the source follower transistor.

### BACKGROUND OF INVENTION

1. Field of the Invention

The present invention relates to a photodiode image sensor device and a process for producing the same. More specifically, the present invention relates to a CMOS image sensor device and a process for producing the same.

2. Description of the Related Art

A photodiode image sensor has been commonly used as an image sensor device. Typically, the photodiode at least includes a reset transistor and a sensing region formed by a diode. In the case that a diode formed by a N type doped region and a P type substrate is used as a sensing region, the photodiode image sensor applies a voltage to a gate of the reset transistor in order to charge a junction capacitor of an N/P diode after the reset transistor turns on. Once the junction capacitor reaches a desirable level, the reset transistor turns off to reverse the N/P diode and thus form a depletion region. When the N/P sensing region is exposed, electrons and holes generated during exposure are separated by an electric field of the depletion region, the electrons moving toward the P type substrate, causing the voltage drop of the N type doped region, and the holes leaving the P type substrate. At this time, if one transistor transmits the electrons of the N type doped region to a bus line and if the charges generated by exposure are also directly transmitted to the bus line without any amplifier, such an image sensor is called a passive pixel photodiode. If the N type doped region is connected to a source follower, formed by a transfer transistor, then the larger current provided by the source follower helps to quickly charge/discharge at the bus line, to stabilize the voltage at the bus line and to minimize the noise. Such an image sensor is called an active pixel photodiode.

A charge coupled device (CCD) has been a popular image sensor because of its advantages such as high dynamic range, low dark current, and well-developed technology. However, there are some problems to solve before the CCD can be further commercialized. For example, specific manufacture processes required to produce the CCD increase the production cost. A CCD driving circuit is operated under high voltage, and thus high energy consumption is required. Furthermore, the CCD can not be random accessed.

The CMOS image sensor device has high quantum efficiency, low read noise, high dynamic range and random-access ability, and can be readily produced by a common process for producing a CMOS. The CMOS image sensor is readily integrated into a chip with other circuits such as control circuits, A/D converters and digital signal circuits to form a system on a chip (SOC). Advanced technology for producing the CMOS image sensor greatly reduces the production cost of the image sensor, the pixel size, and the power consumption of the image sensor. Therefore, the CMOS image sensor has increasingly replaced the CCD.

A conventional process for producing a CMOS image sensor is described as follows. A field oxide is formed in the substrate to define an active region. A gate oxide and a polysilicon gate of the reset transistor are formed on the substrate. An ion implantation process is performed using the field oxide and the polysilicon gate as a mask. Then, a thermal driving process is performed to form a source/drain region and form a doped region to be used as a photodiode sensing region. Then, spacers are respectively formed on sidewalls of the polysilicon gate and the gate oxide. A self-aligned block (SAB) layer is formed over the photodiode sensing region. A CMOS image sensor device is thus achieved.

However, the CMOS image sensor device obtained by the above process still has some drawbacks. In the above process for manufacturing the CMOS image sensor, not only do the steps of forming the source/drain region and the spacers use a plasma process, but also the subsequent processes for forming an interlayer dielectric layer, a contact and a metal line require the plasma process. Plasma process usually needs high operational energy and thus causes considerable voltage drop. The considerable voltage drop easily damages the surface of the photodiode sensing region, especially a bird's beak region around the field oxide, resulting in current leakage in the photodiode sensing region. The current leakage induces undesirably high dark current, increased read noise and lowered device performance.

### SUMMARY OF INVENTION

It is one object of the invention to provide a CMOS image sensor device and a process for producing the same. It is an important feature of the invention to form a buried contact to connect a source region of a reset transistor and a gate of a source follower, that covers not only a photodiode node but also covers a boundary between the photodiode node and a field oxide in a photodiode sensing region so as to protect them from being damaged during subsequent processes.

It is another object of the invention to provide a CMOS image sensor device and a process for producing the same, in which dark current in the CMOS image sensor device can be minimized.

In one aspect of the present invention, a CMOS image sensor device is provided. The device of the invention includes a substrate, a photodiode sensing region, a reset transistor, a source follower transistor and a buried contact (BC). The substrate has an isolation structure that defines an active region. The photodiode sensing region is located in the substrate, and the reset transistor is located on the active region of the substrate and has a source region partially connected to the photodiode sensing region. A first end of the buried contact is located on the substrate between the photodiode sensing region and the reset transistor, and extends over the isolation structure to cover the periphery of the isolation structure and electrically connect the source region of the reset transistor. A second end of the buried contact is located on the active region of the substrate to be used as a gate of the source follower transistor.

In the present invention, the buried contact is formed to cover the whole photodiode sensing region including the periphery of the isolation structure adjacent to the photodiode sensing region. With the use of such a buried contact, the isolation structure can be protected from being damaged during subsequent processes, the occurrence of the dark current can be minimized, and the image sensor performance and the exposure time can be increased. Furthermore, since the buried contact connects the source region of the reset transistor to the gate of the source follower transistor, no additional contact or conductive line is needed. Therefore, the level of device integration can be increased.

In another aspect of the invention, a process for forming a CMOS image sensor device is provided. An isolation structure is formed in the substrate to define an active region. A first well with first type conductivity is formed on the active region of the substrate. A second well with a second type conductivity is formed under the isolation structure. A gate dielectric layer and a first conductive layer are sequentially formed over the substrate, and then patterned to form an opening. The opening exposes a predetermined surface of the substrate for forming a source region of a reset transistor. A first ion implantation process is performed to form a doped region in the substrate under the exposed surface. A second conductive layer is formed over the substrate to fill the opening. The second conductive layer and the first conductive layer are patterned to form a gate of the reset transistor and a third conductive layer. The third conductive layer has a first end extending to a part of the isolation structure and covering the peripheral portion of the isolation structure, and has a second end extending over the active region of the substrate as a gate of the source follower transistor. Then, a thermal process is carried out to repair defects which may be generated on sidewalls of the gate of the transistor and on the third conductive layer, and to drive dopants in the doped region downward and then transversally diffuse them. A second ion implantation process is performed to form a lightly doped region in the substrate outside the sidewalls of the gate. A spacer is formed on each sidewall of the gate of the reset transistor and the third conductive layer. A third ion implantation process is performed to form a heavily doped region in the substrate where a drain region is later formed. Then, a thermal process is performed to turn the lightly doped region and the doped region to a source region of the reset transistor. The source region of the reset transistor extends to the second well with the second conductivity. The heavily doped region and the lightly doped region form a drain region of the reset transistor.

While the gates for the reset transistor, the source follower transistor and the output selection transistor are formed, a buried contact is formed to connect the gate of the source follower transistor to the source region of the reset transistor. One end of the buried contact covers a photodiode node and the periphery of the active region of the photodiode (the periphery of the isolation structure, i.e. the bird's beak area). Therefore, damage on the periphery of the photodiode node during the subsequent processes such as ion implantation, etching of the spacer, or plasma etching can be prevented. Besides, the occurrence of the dark current is minimized and white pixels can be prevented from being formed in arrays of the CMOS image sensor device.

Furthermore, because the source of the reset transistor is electrically connected to the gate of the source follower transistor by means of the buried contact, no additional contact or conductive line is needed. Therefore, the level of device integration can be increased.

### BRIEF DESCRIPTION OF DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 is a schematic circuit layout of a CMOS image sensor device according to one preferred embodiment of the present invention;

FIG. 2 is a top view of the CMOS image sensor device according to one preferred embodiment of the present invention; and

FIGS. 3A to 3F show the schematic, cross-sectional views of the CMOS during production process according to one preferred embodiment of the present invention.

### DETAILED DESCRIPTION

Reference will now be made in detail to the present preferred embodiments of the invention, examples of which are illustrated in the accompanying drawings. Whenever possible, the same reference numbers are used in the drawings and the description to refer to the same or like parts.

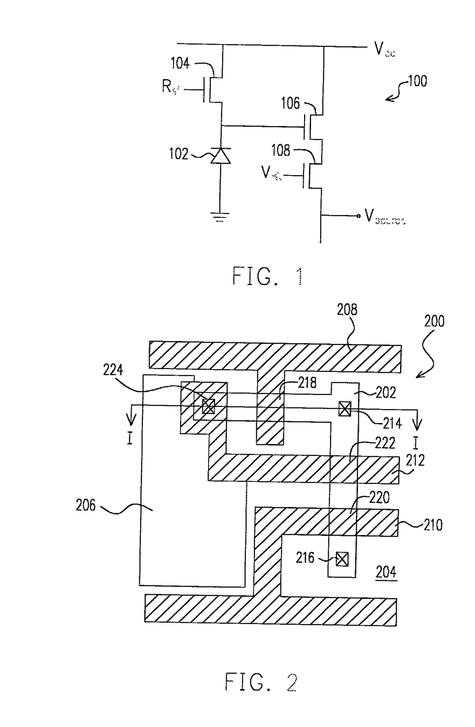

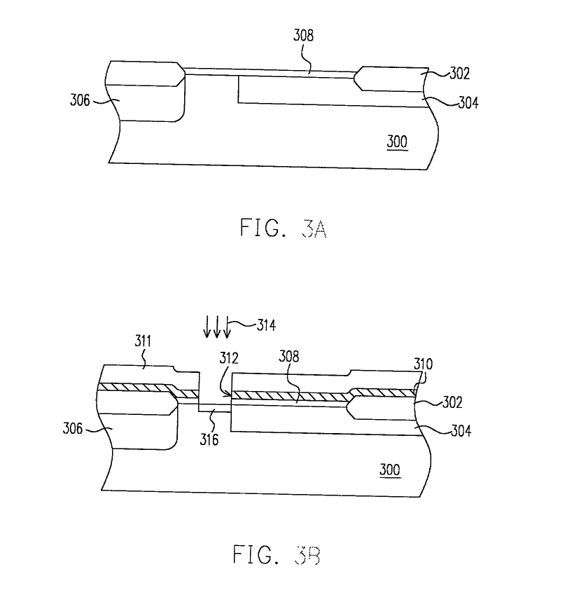

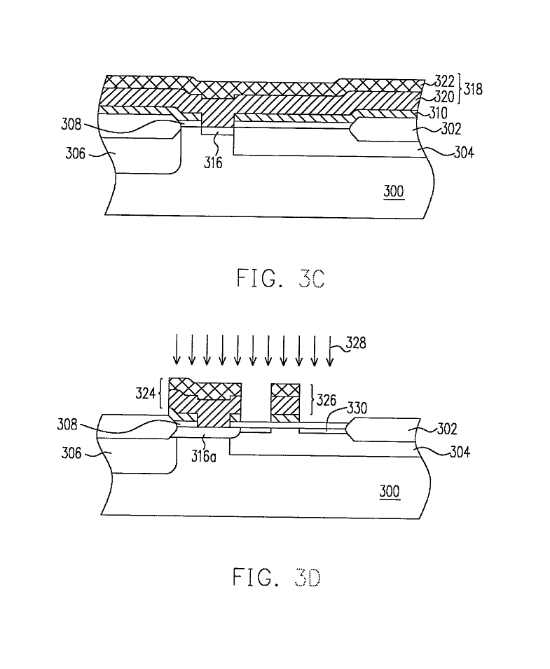

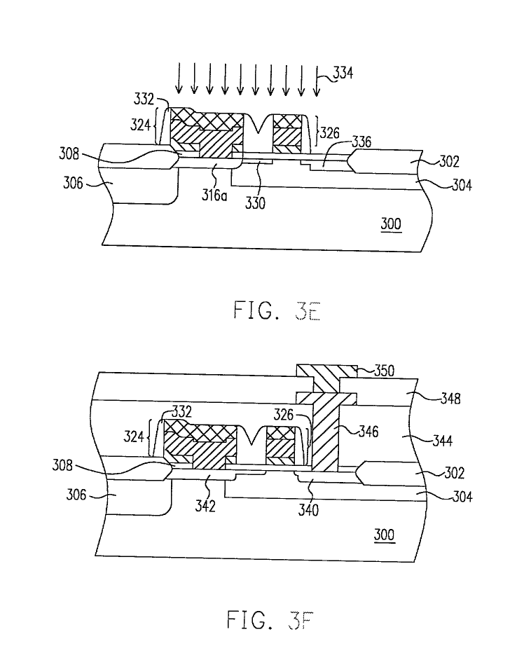

FIG. 1 is a schematic circuit layout of a CMOS image sensor device according to one preferred embodiment of the present invention. FIG. 2 is a top view of the CMOS image sensor device according to one preferred embodiment of the present invention. FIGS. 3A to 3F show the schematic, cross-sectional views of the CMOS during production process according to one preferred embodiment of the present invention.

With reference to FIG. 1, an image sensor device 100 includes a photodiode 102, a reset transistor 104, a source follower 106 and an output selection transistor 108. When the reset transistor 104 is in ON status, the voltage for the reset photodiode 102 is set at reset level. The voltage of the photodiode 102 drops because of exposure to a light source. After the photodiode is exposed for a predetermined period of exposure time, the output selection transistor 108 is set at ON status, and the voltage of the photodiode 102 is sent to a read circuit by driving the source follower 106. Intensity of the light source is determined by the amount of voltage drop of the photodiode 102.

With reference to FIG. 2, an image sensor device 200 includes an active region 202, an isolation structure 204, a photodiode sensing region 206, conductive regions 208, 210, 212, and contacts 214, 216, 224. The isolation structure 204 can be a field oxide, for example. The photodiode sensing region 206 is located under a portion of the isolation structure 204. The photodiode 206 consists of a substrate and a doping region having dopant type different from that of the substrate. When a P type substrate is used, the doping region is doped with N type dopants. When an N type substrate is used, the doping region is doped with P type dopants. In this embodiment of the present invention, a P type substrate with a deep N type well is used. The portion of the conductive layer 208 which traverses a part of the active region 202 serves as a gate of the reset transistor 218. The portion of the conductive layer 210 which traverses a part of the active region 202 serves as a gate of the output selection transistor 220. One end of the conductive layer 212 electrically couples with a source of the reset transistor 218. The conductive layer 212 extends to the isolation structure 204 of the active region 202 to cover the isolation structure 204, specifically, the periphery of the isolation structure 204. The other end of the conductive layer 212, which extends over the other portion of the active region 202, serves as a gate of source follower transistor 222. With the conductive layer 212 capping the isolation structure 204 of the photodiode 206, the isolation structure 204 can be protected from being damaged in sequential processes, thereby reducing the dark-current effect and increasing the image sensor performance and the exposure time.

FIGS. 3A-3F are schematic, cross-sectional views of the CMOS image sensor device of FIG. 2 taken along line I-I, during the production process.

With reference to FIG. 3A, a substrate 300 is provided. The substrate 300 can be a P type substrate. An isolation structure 302 is formed on the substrate 300 to define an active region for a photodiode sensing region and a transistor device. The isolation structure 302 can be a field oxide layer made of silicon oxide, for example. Formation of the field oxide layer can be achieved by Local Oxidation process. Then, a P type 304 and an N type well (not shown) are formed in the substrate 300. The P type well 304 and the N type well can be formed by, for example, forming a first mask (not shown) on the substrate 300 to expose a predetermined area for forming the P type well 304, and then performing a first implantation process to form a P type well 304 in the substrate 300. A dopant used in the first implantation process can be boron ions, for example. The substrate 300 is then subject to a thermal process to downwardly extend the P type well 304. After the first mask is removed, a second mask (not shown) is formed on the substrate 300 to expose a predetermined area for forming the N type well (not shown). A second ion implantation process is performed to form an N type well in the substrate 300. The dopant used in the second ion implantation process can be phosphorous ions, for example. Then, a thermal process is performed to deepen the N type well.

A deep N type well region 306 is formed in the substrate 300. The deep N type well 306 can be closely formed under the isolation structure 302. Formation of the deep N type well 306 can be achieved by forming a third mask (not shown) on the substrate 300 to expose a predetermined area for forming the deep N type well 306, and then performing a third implantation process to form the deep N type well 306 in the substrate 300. A dopant used in the third implantation process can be phosphorous ions, for example. The energy for the third implantation process can be 1000-2000 KeV, for example. Subsequently, a thermal process is performed to downwardly extend the deep N type well 306.

Then, a gate dielectric layer 308 is formed on the substrate 300. The gate dielectric layer 308 can be made of silicon oxide, for example. The thickness of the gate dielectric layer 308 is about 90 angstroms, for example. Formation of the gate dielectric layer 308 can be achieved by thermal oxidation process.

With reference to FIG. 3B, a conductive layer 310 is formed over the substrate 300. The conductive layer 310 can be formed of polysilicon, for example. The thickness of the conductive layer 310 is about 500 angstroms, for example. The photoresist 311 is formed on the conductive layer 310. The photoresist 311, the conductive layer 310 and the gate dielectric layer 308 are patterned to form an opening 312 exposing a predetermined area of the substrate 300 for forming the source of the reset transistor. A fourth ion implantation process 314 is performed to form a doped region 316 in the substrate 300. The dopant used in the fourth implantation process is phosphorous ions, for example. The energy for the fourth implantation process is in the range of 15 30 KeV, with an implantation dosage of about 1×10¹⁴ atoms/cm², for example. The doped region 316 is located between the P type well 304 and deep N type well 306.

With reference to FIG. 3C, a conductive layer 318 is formed over the substrate 300. The conductive layer 318 covers the opening 312 and electrically connects to the doped region 316. The conductive layer 318 can be formed of policide, for example. The conductive layer 318 can include a doped polysilicon 320 and a tungsten silicide 322. The doped polysilicon 320 can be formed by in-situ ion doping method using CVD. The doped polysilicon 320 has a thickness of about 1000 angstroms, for example. The tungsten silicide 322 can be formed by LPCVD, with a thickness of about 1200 angstroms, for example. Before the doped polysilicon is formed, a cleaning process can be performed using diluted hydrogen fluoride as a cleaning solution to remove the native oxide and pollutants on the substrate 300.

With reference to FIG. 3D, the conductive layers 318 and 310 are patterned by photolithography to form a conductive line 324 and a gate 326 on an active region of the substrate 300. One side of the conductive line 324 covers the periphery of the isolation structure 302 of a photodiode sensing region of the substrate. The other side of the conductive line 324 serves as a gate for the source follower transistor (not shown). Then, a thermal repair process is performed after the conductive layers 318 and 310 are patterned to repair defects which may occur on sidewalls of the gate 326 and the conductive line 324, and to further drive the dopants of the doped region 316 down and then diffuse transversely to form a doped region 316a. A fifth implantation process 328 is performed using the isolation structure 302, the conductive line 324 and the gate 326 as masks to form a lightly doped region in the substrate 300 outside the gate 326. A dopant used in the fifth implantation process 328 can be N type phosphorous or arsenic ions, or P type boron ions.

With reference to FIG. 3E, a spacer 332 is formed respectively on sidewalls of the conductive line 324 and the gate 326. The spacer 332 can be formed of silicon oxide, for example. Formation of the spacer 332 can be achieved by CVD using tetra-ethyl ortho silicate (TEOS)/ozone as a gaseous reactant to form a silicon oxide layer (not shown), and then anisotropically etching the silicon oxide layer to form the spacers 332. Thereafter, the substrate 300 is subject to an ion implantation process using the spacers 332 of the conductive line 324 and the gate 326 as a mask to form a heavily doped region 336 in the substrate where a drain region is later formed. A dopant used in the ion implantation process 334 can be N type phosphorous or arsenic ions, or P type boron ions. Because the distance between the conductive line 324 and the gate 326 is substantially small, a residual part of the silicon oxide undesirably remains after the spacers 332 are formed. The residual silicon oxide blocks dopants used in a subsequent ion implantation process 334. The heavily doped region will therefore not be formed between the conductive line 324 and the gate 326.

With reference to 3F, a thermal process is carried out to drive the dopants into the substrate 300 to respectively form a source region 342 and a drain region 340 of the reset transistor outside the sides of the gate 326 in the substrate 300. The source region 342 includes a lightly doped region 330 and a doped region 316a. The source region 342 extends to the deep N type well 306 in the P type well 304. That is, the source region 342 is connected to the photodiode sensing region and has the same dopant type as the source region 342 of the reset transistor. The drain region 340 includes a lightly doped 330 region and the heavily doped region 336. Then, an interlayer dielectric layer 344 is formed over the substrate 300. A contact 346 is formed in the interlayer dielectric layer 344 to electrically connect the drain region 340. An intermetal dielectric layer 348 is formed over the substrate 300. A conductive line 350 is formed on the intermetal dielectric layer 348 to electrically connect the contact 346. The subsequent process for completing the CMOS image sensor device is well known and thus is omitted herein.

In the above embodiment of the present invention, while the gates for the reset transistor, the source follower transistor and the output selection transistor are formed, a buried contact is formed to connect the gate of the source follower transistor to the source region of the reset transistor. One end of the buried contact covers a photodiode node and the periphery of the active region of the photodiode (the periphery of the isolation structure, i.e. the bird beak area). Therefore, damage on the periphery of the photodiode node during the subsequent processes such as ion implantation, etching of the spacer, or plasma etching can be prevented. Besides, the occurrence of the dark current is minimized and white pixels can be prevented from being formed in arrays of the CMOS image sensor device.

Furthermore, because the source of the reset transistor is electrically connected to the gate of the source follower transistor by means of the buried contact, no additional contact or conductive line is needed. Therefore, the level of device integration can be increased.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

1. A CMOS image sensor device comprising:
a substrate having an isolation structure that defines an active region;
a photodiode sensing region located in the substrate;
a reset transistor located on the active region of the substrate, wherein the reset transistor has a source region connected to a part of the photodiode sensing region; and
a buried contact, wherein a first end of the buried contact is located on the substrate between the photodiode sensing region and the reset transistor and extended over the isolation structure to cover the periphery of the isolation structure and electrically connect the source region of the reset transistor, and wherein a second end of the buried contact is located on the active region of the substrate to be used as a gate of a source follower transistor.

2. The CMOS image sensor device of claim 1, wherein the photodiode sensing region is located under the isolation structure.

3. The CMOS image sensor device of claim 1, wherein a spacer is formed on a sidewall of the buried contact.

4. The CMOS image sensor device of claim 1, wherein the photodiode sensing region further comprises a doped region with the same conductivity as the source region of the reset transistor.

6. The CMOS image sensor device of claim 1, wherein a P type well is further formed under the reset transistor.

7. The CMOS image sensor device of claim 1, wherein the substrate is a first type conductivity substrate and the photodiode sensing region comprises a second conductivity doped region.

8. The CMOS image sensor device of claim 1, wherein the substrate is a P type substrate, and the photodiode sensing region comprises a deep N type well.

9. A process for producing a CMOS image sensor device, comprising:
providing a substrate;
forming an isolation structure in the substrate to define an active region;
forming a first well with first conductivity in the active region of the substrate;
forming a second well with second conductivity under the isolation structure in the substrate;
forming a gate dielectric layer over the substrate;
forming a first conductive layer over the gate dielectric layer;
patterning the first conductive layer and the gate dielectric layer to form an opening, wherein the opening exposes a predetermined surface of the substrate;
performing a first ion implantation process to form a doped region in the substrate under the exposed surface;
forming a second conductive layer over the substrate to fill the opening;
patterning the second conductive layer and the first conductive layer to form a gate of the reset transistor and a third conductive layer, wherein the third conductive layer has a first end extending over the isolation structure and covering a peripheral portion of the isolation structure, and wherein the third conductive layer has a second end extending to the active region of the substrate to be as a gate of a source follower transistor;
performing a thermal process to repair defects which occur on the sidewalls of the gate of the reset transistor and the third conductive layer, and drive the dopant of the doped region downward and then transversely diffuse them;
performing a second ion implantation process to form a lightly doped region in the substrate outside sidewalls of the gate;
forming a spacer respectively on the sidewalls of the gate of the reset transistor and the third conductive layer;
performing a third ion implantation process to form a heavily doped region in the substrate where a drain region is later formed; and
performing a thermal process to turn the lightly doped region and the doped region into a source region of the reset transistor, wherein the source region extends to the second well with second conductivity, and the heavily doped region and the lightly doped region form a drain region of the reset transistor.

10. The process for producing the CMOS image sensor device of claim 9, wherein a material of the gate dielectric layer is silicon oxide.

11. The process for producing the CMOS image sensor device of claim 9, wherein the substrate is a P type silicon substrate.

12. The process for producing the CMOS image sensor device of claim 9, wherein the first well with first conductivity is a P type well.

13. The process for producing the CMOS image sensor device of claim 9, wherein the second well with second conductivity is a deep N type well.

14. The process for producing the CMOS image sensor device of claim 9, wherein a material of the second conductive layer is a polycide.

15. The process for producing the CMOS image sensor device of claim 9, further comprising a cleaning step to remove a native oxide and pollutants on the surface of the substrate, before forming a second conductive layer.

16. The process for producing the CMOS image sensor device of claim 15, wherein a diluted hydrogen fluoride solution is used as a cleaning liquid in the cleaning step.
